(19) United States
(12) Patent Application Publication
(10) Pub. No.: US 2025/0275366 A1
(43) Pub. Date: Aug. 28, 2025

(54) TRANSISTOR AND DISPLAY DEVICE INCLUDING THE SAME

(71) Applicant: LG Display Co., Ltd., Seoul (KR)

(72) Inventor: Sung Ho MOON, Paju-si (KR)

(73) Assignee: LG Display Co., Ltd., Seoul (KR)

(21) Appl. No.: 19/067,220

(22) Filed: Feb. 28, 2025

(30) Foreign Application Priority Data
Feb. 28, 2024 (KR) 10-2024-0029163

(51) Int. Cl. H10K 59/121; H10D 30/67; H10K 59/124; H10K 59/131

(52) U.S. Cl. CPC H10K 59/1213; H10D 30/6736; H10K 59/124; H10K 59/131

(57) ABSTRACT

A transistor and a display device including the same are discussed. The transistor can include an active layer, a gate electrode having a region overlapping with the active layer, a gate insulating layer disposed between the active layer and the gate electrode, and a plurality of holes in the gate insulating layer at an outside of the overlap area between the gate electrode and the active layer.

### CROSS-REFERENCE TO RELATED APPLICATIONS

This application claims priority to Korean Patent Application No. 10-2024-0029163, filed in the Republic of Korea on Feb. 28, 2024, the entire contents of which are hereby expressly incorporated by reference into the present application.

### BACKGROUND OF THE INVENTION

### Field of the Invention

The present disclosure relates to a transistor, and more particularly to a transistor capable of enhancing reliability and a display device including the same.

### Discussion of the Related Art

In a TV, a monitor, a smartphone, a tablet computer, a notebook computer, etc., display devices of various types and forms are used to display an image.

Such a display device includes a plurality of pixels in order to render an image, and is provided with a transistor in order to control the operation of the pixels on a pixel basis.

Such a display device, which includes a plurality of pixels, is provided with a plurality of driving and switching elements in order to drive and control the pixels. The driving and switching elements can include transistors. Such transistors are widely applied not only to the pixels, but also to an integrated circuit.

Recently, a variety of research and development have been conducted for an enhancement in performance of transistors and an enhancement in reliability of transistors.

### SUMMARY OF THE INVENTION

Accordingly, the present disclosure is directed to a transistor and a display device including the same that substantially obviate one or more problems due to limitations and disadvantages of the related art.

It is an object of the embodiments of the present disclosure to secure an effective channel length through provision of hydrogen discharge paths at an outside of a channel of an active layer.

It is another object of the embodiments of the present disclosure to prevent deviations of channel length variation by disposing hydrogen discharge paths of an active layer at an outside of a central region of a channel and at an outside of an edge region of the channel at different densities, thereby differently adjusting channel length variation in different regions.

It is another object of the embodiments of the present disclosure to enhance reliability of a transistor including an oxide semiconductor through control of effective channel length variation of the transistor.

It is another object of the embodiments of the present disclosure to provide a transistor having a structure with a wide channel width, which is capable of preventing or reducing effective channel length variation and, as such, preventing threshold voltage fluctuation in an area where the wide-width transistor is disposed.

It is another object of the embodiments of the present disclosure to provide a display device including a wide-width transistor having element stability in an active area or a non-active area.

It is another object of the embodiments of the present disclosure to provide a transistor including a structure capable of enabling discharge of hydrogen and, as such, achieving an enhancement in reliability in the case in which, as the transistor, a wide-width transistor is provided at a gate-in-panel requiring high power, and to provide a display device including the transistor.

It is another object of the embodiments of the present disclosure to achieve high freedom of design through a reduction in sensitivity according to channel width variation, thereby enabling disposition of a high-power transistor with a small size in a non-active area and, as such, realizing a narrow bezel.

It is still another object of the embodiments of the present disclosure to provide a display device capable of reducing defect rates thereof, thereby reducing use amounts of materials used in the overall manufacturing process, such as gases, an etchant, etc. for manufacture thereof, and, as such, reducing generation of greenhouse gases caused by the manufacturing process.

Objects of the present disclosure are not limited to the above-described object, and other objects of the present disclosure not yet described will be more clearly understood by those skilled in the art from the following detailed description.

To achieve these objects and other advantages and in accordance with the purpose of the disclosure, as embodied and broadly described herein, a transistor includes an active layer, a gate electrode having a region overlapping with the active layer, a gate insulating layer disposed between the active layer and the gate electrode, and a plurality of holes in the gate insulating layer at an outside of the overlap area between the gate electrode and the active layer.

According to aspects of the present disclosure, a disposition density of the plurality of holes can be higher in a region adjacent to an edge of the active layer in a width direction of the active layer than in a region adjacent to a center of the active layer in the width direction.

### BRIEF DESCRIPTION OF THE DRAWINGS

The accompanying drawings, which are included to provide a further understanding of the disclosure and are incorporated in and constitute a part of this application, illustrate embodiment(s) of the disclosure and along with the description serve to explain the principle of the disclosure. In the drawings:

FIG. 1 is a schematic plan view showing a display device according to one or more embodiments of the present disclosure;

FIG. 2 is a circuit diagram showing a sub-pixel according to an embodiment of the present disclosure;

FIG. 3 is a circuit diagram showing a configuration of a gate-in-panel according to an embodiment of the present disclosure;

FIG. 4 is a plan view showing a transistor according to a first embodiment of the present disclosure;

FIG. 5 is a cross-sectional view taken along line I-I′ in FIG. 4;

FIG. 6 is a cross-sectional view taken along line II-II' in FIG. 4;

FIG. 7 is a plan view showing a transistor according to a second embodiment of the present disclosure;

FIG. 8 is a cross-sectional view taken along line III-III' in FIG. 7;

FIG. 9 is a plan view showing a transistor according to a third embodiment of the present disclosure; and

FIG. 10 is a cross-sectional view showing a display device according to one or more embodiments of the present disclosure.

### DETAILED DESCRIPTION OF THE EMBODIMENTS

Hereinafter, various embodiments of the present disclosure will be described in detail with reference to the accompanying drawings. In the following description of the present disclosure, where the detailed description of the relevant known steps, elements, functions, technologies, and configurations can unnecessarily obscure an important point of the present disclosure, a detailed description of such steps, elements, functions, technologies, and configurations can be omitted. In addition, the names of elements used in the following description are selected in consideration of clarity of description of the specification, and can differ from the names of elements of actual products.

The shapes, sizes, ratios, angles, numbers, and the like, which are illustrated in the drawings to describe various example embodiments of the present disclosure are merely given by way of example. The disclosure is not limited to the illustrations in the drawings. In the present disclosure, where terms such as “including,” “having,” “comprising,” and the like are used, one or more components can be added, unless the term, such as “only,” is used. The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise. Further, the term “can” fully encompasses all the meanings and coverages of the term “may.”

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components, and may not define order or sequence. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

Now, a transistor and a display device including the transistor according to various embodiments of the present disclosure will be discussed referring to the drawings. All the components of each transistor and each display device according to all embodiments of the present disclosure are operatively coupled and configured.

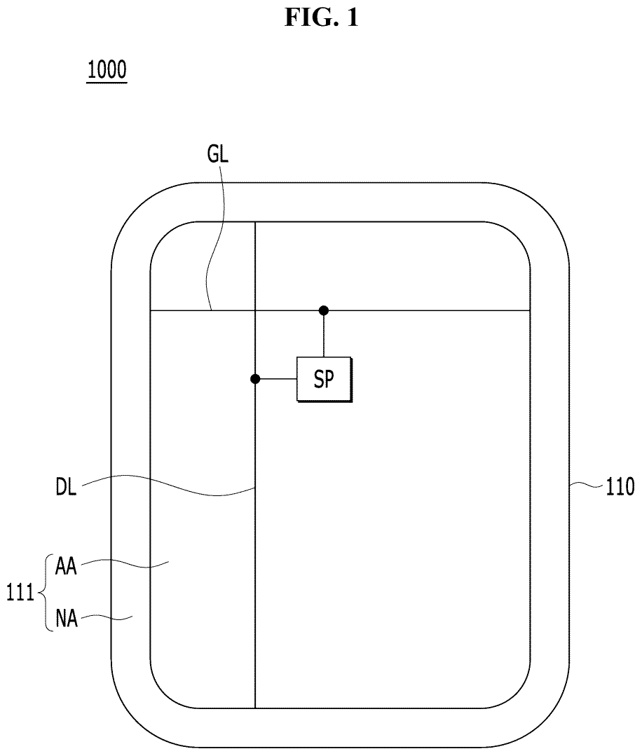

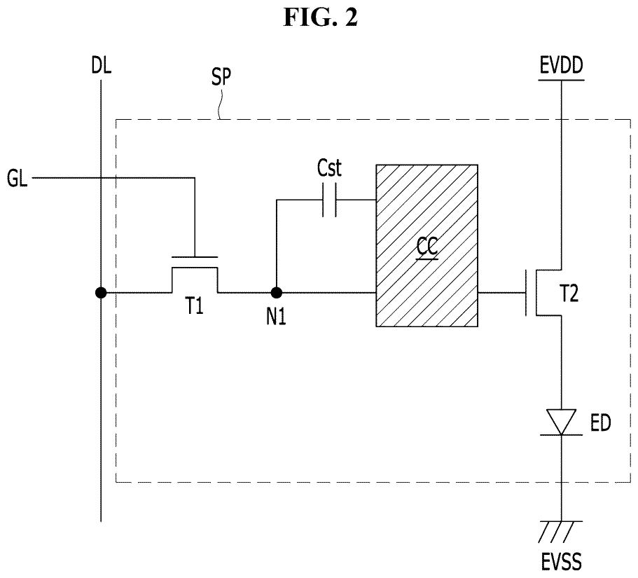

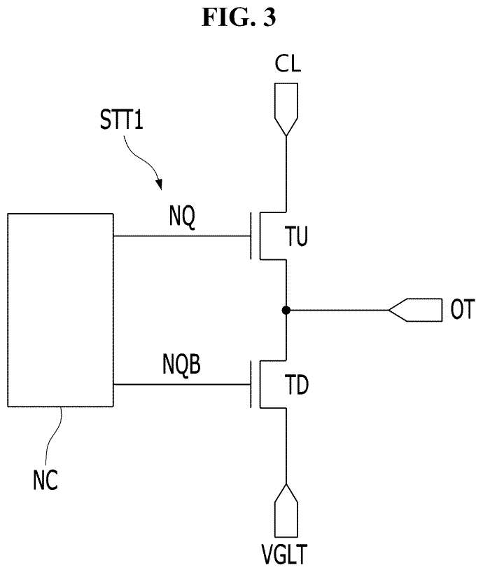

FIG. 1 is a schematic plan view showing a display device according to one or more embodiments of the present disclosure. FIG. 2 is a circuit diagram showing a sub-pixel according to an embodiment of the present disclosure. FIG. 3 is a circuit diagram showing a configuration of a gate-in-panel according to an embodiment of the present disclosure.

Referring to FIGS. 1 and 2, the display device according to the embodiment(s) of the present disclosure, which is designated by reference numeral “1000”, can include a display panel 110, and a case configured to accommodate a side surface of the display panel 110 and a lower portion of the display panel 110. A non-active area NA of the display panel 110 can be hidden by the case or can be covered by a separate printed film. A printed circuit film and/or a battery can be interposed between the lower portion of the display panel 110 and the case.

The display panel 110 can include a substrate 111 including an active area AA (or display area) together with the non-active area NA (or non-display area) surrounding the active area AA, and a driver connected to the substrate 111. The non-active area NA can surround the active area AA entirely or only in part(s). The driver can be formed to be integrated in the substrate 111 together with a configuration of an array provided in the active area AA, can be connected to the substrate 111 in a chip-on-glass manner, or can be connected to a printed circuit board installed at the substrate 111 through a film having a chip-on-film structure or a connector. Otherwise, the driver can include both the configuration integrated in the substrate 111 and an external COG (Chip-On-Glass) or COF (Chip-On-Film) configuration.

The active area AA is an area configured to display an image. In the active area AA of the display panel 110, a plurality of sub-pixels SP can be disposed. As such, the active area AA can display an image using the plurality of sub-pixels SP. An area other than the active area AA can be the non-active area NA.

The non-active area NA can be disposed in a peripheral area surrounding the active area AA configured to display an image. At least one driver configured to drive the plurality of sub-pixels SP can be disposed in the non-active area NA. The driver can include a gate-in-panel (GIP). The gate-in-panel (GIP) can be connected to a plurality of gate lines GL of the active area AA and, as such, can sequentially supply a gate voltage to the plurality of gate lines GL.

In the non-active area NA, a variety of additional elements configured to drive the sub-pixels SP in the active area AA can be further disposed.

As shown in FIG. 2, at least one of the plurality of sub-pixels SP can include a first transistor T1, a second transistor T2, a storage capacitor Cst, a compensation circuit CC, and a light emitting element ED.

For example, the first transistor T1 can be a switching transistor, and the second transistor T2 can be a driving transistor.

A first electrode (for example, a drain electrode) of the first transistor T1 is electrically connected to a data line DL, and a second electrode (for example, a source electrode) is electrically connected to a first node N1. A gate electrode of the first transistor T1 is electrically connected to a gate line GL. The first transistor T1 transmits, to the first node N1, a data signal supplied thereto through the data line DL in response to a scan signal supplied thereto through the gate line GL.

The storage capacitor Cst is electrically connected to the first node N1 and, as such, charges a voltage applied to the first node N1 therein.

A first electrode (for example, a drain electrode) of the second transistor T2 receives a high-level drive voltage EVDD. A second electrode (for example, a source electrode) of the second transistor T2 is electrically connected to a first electrode (for example, an anode) of the light emitting element ED. The second transistor T2 can control the amount of drive current flowing through the light emitting element ED, in response to a voltage applied to a gate electrode thereof.

A semiconductor layer of the first transistor T1 and/or the second transistor T2 can include silicon such as amorphous silicon (a-Si), polycrystalline silicon (poly-Si), low-temperature polycrystalline silicon (LTPS) or the like, or can include an oxide such as indium-gallium-zinc oxide (IGZO), without being limited thereto. At least one of the first and second transistors T1 and T2 includes an oxide semiconductor layer and, as such, can be formed at a low temperature and can have high mobility while maintaining amorphous characteristics, as compared to the case in which a material different from that of the oxide semiconductor layer is used.

The light emitting element ED outputs light corresponding to drive current. The light emitting element ED can output light corresponding to one of red, green, blue, and white.

The light emitting element ED can include the anode, an intermediate layer disposed on the anode, and a cathode configured to supply a common voltage. The intermediate layer includes at least one emission layer and, as such, can be implemented to emit light of the same color, for example, white light, for different pixels, or can be implemented to emit light of different colors, for example, red light, green light, or blue light, for different sub-pixels SP. The intermediate layer can include various kinks of common layers and functional layers in order to efficiently supply holes and electrons to the emission layer.

The light emitting element ED can be a top-emission type diode or a bottom-emission type diode.

The compensation circuit CC can be additionally provided in the sub-pixel SP in order to compensate a threshold voltage of the second transistor T2, etc. The compensation circuit CC can be constituted by one or more transistors. The compensation circuit CC can include one or more transistors and a capacitor, and can be diversely configured in accordance with compensation methods. The sub-pixel SP including the compensation circuit CC can include a circuit having various structures respectively having different numbers of transistors and/or capacitors, such as 3T1C, 4T2C, 5T2C, 6T1C, 6T2C, 7T1C, 7T2C, etc.

Among the transistors provided at the sub-pixel SP, the switching transistor can require high-speed driving thereof, for rapid switching operation thereof.

The gate-in-panel (GIP) included in the non-active area NA outputs gate signals to gate lines in accordance with a gate control signal input thereto from a timing controller. The gate-in-panel (GIP) can include a plurality of transistors, and the plurality of transistors can be formed in the same process as that of the transistors of the sub-pixel SP.

For example, as shown in FIG. 3, the gate-in-panel (GIP) can include stages STT1 connected to one another in a dependent manner, and the stages STT1 can sequentially output gate signals to the gate lines, respectively.

Each of the stages STT1 includes a pull-up node NQ, a pull-down node NQB, a pull-up transistor TU configured to be turned on when the pull-up node NQ is charged with a gate-high voltage, a pull-down transistor TD configured to be turned on when the pull-down node NQB is charged with a gate-high voltage, and a node controller NC configured to control charge and discharge of the pull-up node NQ and the pull-down node NQB.

The node controller NC can be connected to a start signal line, to which a start signal or a carry signal of an upstream stage is input, and a clock line, to which one of gate clock signals is input. The node controller NC controls charge and discharge of the pull-up node NQ and the pull-down node NQB in accordance with the start signal or the carry signal of the upstream stage input to the start signal line and the gate clock signal input to the clock line. In order to stably control an output of the stage STT1, the node controller NC discharges the voltage of the pull-down node NQB to be a gate-low voltage when the pull-up node NQ is charged with a gate-high voltage, and discharges the voltage of the pull-up node NQ to be a gate-low voltage when the pull-down node NQB is charged with a gate-high voltage. For these functions, the node controller NC can include a plurality of transistors.

When the stage STT1 is pulled up, for example, when the pull-up node NQ is charged with a gate-high voltage, the pull-up transistor TU is turned on, thereby outputting a gate clock signal of a clock line CL to an output terminal OT. When the stage STT1 is pulled down, for example, when the pull-down node NQB is charged with a gate-high voltage, the pull-down transistor TD is turned on, thereby discharging the output terminal OT to a gate-low voltage of a gate-low voltage terminal VGLT.

In the example of FIG. 3, each of the pull-up transistor TU, the pull-down transistor TD, and the plurality of transistors of the node controller NC in each of the stages STT1 of the gate-in-panel (GIP) can be a transistor having a channel with a wide width for fast response.

In addition, although each of the pull-up transistor TU, the pull-down transistor TD, and the plurality of transistors of the node controller NC in each of the stages STT1 of the gate-in-panel (GIP) is illustrated in FIGS. 2 and 3 as being constituted by an N-type semiconductor transistor having N-type semiconductor characteristics, the embodiments of the present disclosure are not limited thereto. That is, each of the pull-up transistor TU, the pull-down transistor TD, and the plurality of transistors of the node controller NC in each of the stages STT1 of the gate-in-panel (GIP) can be constituted by a P-type semiconductor transistor having P-type semiconductor characteristics.

The display panel 110 can include a data driver in addition to the gate-in-panel (GIP). For example, the data driver can include at least one source drive integrated circuit (referred to as “IC” hereinafter). The source drive IC receives digital video data and a source control signal from the timing controller. The source drive IC converts the digital video data into analog data voltages in accordance with the source control signal, and then supplies the analog data voltages to data lines DL.

When the source drive IC is constituted by a drive chip such as an integrated circuit, the source drive IC can be mounted on a flexible film in a chip-on-film (COF) manner. At the flexible film, wirings configured to connect the source drive IC to pads and wirings configured to connect the pads to wirings of a circuit board are formed. The flexible film is attached to pads such as data pads formed in the non-active area NA of the display panel 110, using an anisotropic conducting film and, as such, the pads and the wirings of the flexible film can be interconnected.

As described above, in the display device according to the embodiment of the present disclosure, each of the sub-pixels SP includes at least one transistor as a switching element, and includes a plurality of transistors in order to sequentially output gate signals to the gate lines when the gate-in-panel (GIP) is provided as a driver in the non-active area NA. In a display device requiring fast driving due to high resolution, it is desirable for a plurality of transistors of a gate-in-panel (GIP) to have increased fast response in order to enable the gate-in-panel (GIP) to output stable gate signals. To this end, each transistor of the gate-in-panel (GIP) can be required to be implemented as a wide-width transistor.

Hereinafter, a thin film transistor having an oxide semiconductor layer, which is applicable to transistors of sub-pixels SP, transistors of a gate-in-panel (GIP), etc. in a display device requiring fast driving due to high resolution, in accordance with an embodiment of the present disclosure, will be described in detail.

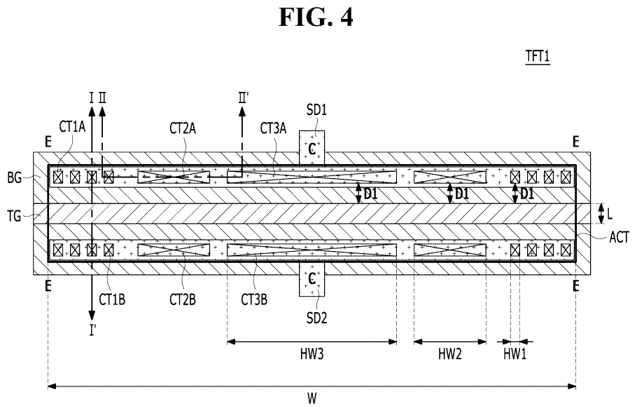

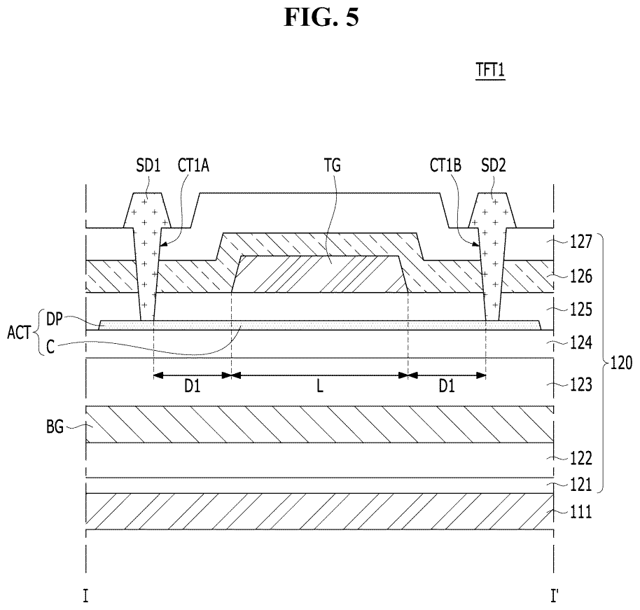

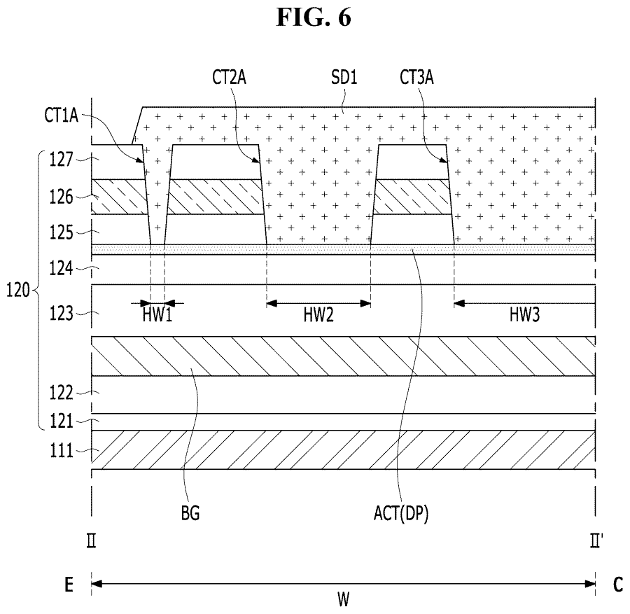

FIG. 4 is a plan view showing a transistor according to a first embodiment of the present disclosure. FIG. 5 is a cross-sectional view taken along line I-I′ in FIG. 4. FIG. 6 is a cross-sectional view taken along line II-II' in FIG. 4.

As shown in FIGS. 4 to 6, the transistor according to the first embodiment of the present disclosure includes an active layer ACT, a gate electrode TG having a region overlapping with the active layer ACT, and a gate insulating layer 125 disposed between the active layer ACT and the gate electrode TG.

In addition, in the transistor according to the first embodiment of the present disclosure, the active layer ACT has a width W and a length L in the region overlapping with the gate electrode TG, and has a shape extending lengthily in a width (W) direction. The width W and the length L have directions intersecting each other, respectively.

The active layer ACT has a channel in the region overlapping with the gate electrode TG. When different voltages are supplied to first and second source-drain electrodes SD1 and SD2 at opposite sides of the gate electrode TG, respectively, movement of charges can be generated in the channel.

The width (W) direction of the active layer ACT can be a direction parallel to the gate line GL or the data line DL shown in FIG. 1.

The region of the active layer ACT overlapping with the gate electrode TG is an intrinsic region, that is, a region not doped with impurities, and, as such, can function as a channel. Regions of the active layer ACT beyond the gate electrode TG are regions doped with impurities, that is, regions having conductivity. When these regions are connected to the first source-drain electrode SD1 and the second source-drain electrode SD2, respectively, a small resistance is exhibited at connection areas. Impurity doping can be carried out using the gate electrode TG as a mask. For example, it can be possible to form conductive regions in the regions of the active layers ACT beyond the gate electrode TG by implanting impurities such as boron, phosphorous, or fluorine in the active layer ACT through the gate insulating layer 125 at opposite sides of the gate electrode TG after forming the gate insulating layer 125 and the gate electrode TG on the active layer ACT. However, examples of the impurities are not limited to boron, phosphorous, and fluorine. Taking into consideration crystalline or amorphous properties of the active layer ACT, these elements can be substituted by an element having a molecular weight different from those of the elements, so long as the element exhibits conductive characteristics when the element is doped.

Opposite portions of the active layer ACT are connected, through first contact holes CT1A, CT2A and CT3A and second contact holes CT1B, CT2B and CT3B, to the first source-drain electrode SD1 and the second source-drain electrode SD2 disposed to be spaced apart from each other under the condition that the gate electrode TG is interposed therebetween, respectively.

Each of the first and second source-drain electrodes SD1 and SD2 extends in a direction not overlapping with the active layer ACT and, as such, can be connected to an external line. In FIG. 4, each of the first and second source-drain electrodes SD1 and SD2 is shown as having a “T” shape extending lengthily in the width (W) direction while protruding outwards from a central portion C of the active layer ACT in the width (W) direction. However, the shapes of the first and second source-drain electrodes SD1 and SD2 are not limited to the shown shape, and can be varied to be an “L” shape in which a protrusion portion is disposed at an edge portion E of the active layer ACT in the width (W) direction.

In the first embodiment of the present disclosure, the first and second source-drain electrodes SD1 and SD2 have a common feature in that the first and second source-drain electrodes SD1 and SD2 have a “-” shape extending lengthily in the width (W) direction of the active layer ACT. In accordance with the common feature, the contact holes CT1A, CT2A, CT3A, CT1B, CT2B, and CT3B for connection of the first and second source-drain electrodes SD1 and SD2 having the “-” shape extending lengthily in the width (W) direction of the active layer ACT to the active layer ACT can be used as hydrogen discharge paths while having different widths in different regions, respectively. Hydrogen discharge can be carried out after formation of the contact holes CT1A, CT2A, CT3A, CT1B, CT2B, and CT3B and before formation of the first and second source-drain electrodes SD1 and SD2.

When the transistor according to the embodiment of the present disclosure is provided in an active area AA, one of the first and second source-drain electrodes SD1 and SD2 can be electrically connected to the data line DL, and the other of the first and second source-drain electrodes SD1 and SD2 can be electrically connected to the anode of the light emitting element ED. When the transistor according to the embodiment of the present disclosure is provided in a non-active area NA, one of the first and second source-drain electrodes SD1 and SD2 can be electrically connected to the gate line GL and, as such, can be used to supply a gate voltage. In this case, the electrical connection can not only include a direct connection, but also can include a connection having addition of a separate transistor or a separate capacitor between two configurations to be interconnected.

In the transistor according to the embodiment of the present disclosure, the overlap region between the gate electrode TG and the active layer ACT is long in the width (W) direction while being short in a length (L) direction and, as such, the channel is short in the length (L) direction. Accordingly, charges move through the short channel between the first and second source-drain electrodes SD1 and SD2 and, as such, high mobility can be achieved, and fast operation can be possible. In addition, since the active layer ACT and the first and second source-drain electrodes SD1 and SD2 are disposed to extend lengthily in the width (W) direction, the area of the channel in the width (W) direction increases. Accordingly, the transistor can be used as a high-power transistor because generation of high current is possible, as compared to a short-width transistor. The wide-width transistor can be included in a circuit configuration requiring high power in the non-active area NA. For example, the wide-width transistor can be used as a buffer transistor of a gate-in-panel (GIP) or a transistor included in an anti-static circuit.

In the transistor according to the embodiment of the present disclosure, holes functioning as hydrogen discharge paths can be formed together with the contact holes CT1A, CT2A, and CT3A in a process for forming the contact holes CT1A, CT2A, and CT3A. Accordingly, it can be possible to solve problems such as hydrogen diffusion, etc. without addition of a separate process and, as such, there is an advantage of process optimization.

The transistor according to the embodiment of the present disclosure can be provided in an area requiring high power, such as the gate-in-panel (GIP), and a hydrogen discharge structure is provided within the structure of the transistor. Accordingly, it can be possible to prevent a variation in effective channel length of the transistor and, as such, to enhance reliability of the transistor.

In the transistor according to the first embodiment of the present disclosure, as shown in FIG. 4, the first contact holes CT1A, CT2A, and CT3A and the second contact holes CT1B, CT2B, and CT3B have a greatest width HW3 at the central portion C in the width (W) direction of the active layer ACT while having a smallest width HW1 at the edge portion E in the width (W) direction of the active layer ACT.

Although FIG. 4 shows an example in which the first and second contact holes have a first width HW1 at the edge portion E in the width (W) direction of the active layer ACT, a third width HW3 at the central portion C in the width (W) direction of the active layer ACT, and a second width HW2 at a portion between the central portion C and the edge portion E in the width (W) direction of the active layer ACT, embodiments of the present disclosure are not limited thereto. The number of the first and second contact holes between the active layer ACT and the first and second source-drain electrodes can be two such that the two contact holes have different widths, respectively, or can be four or more such that the four or more contact holes have different widths, respectively.

The first contact holes CT1A, CT2A, and CT3A and the second contact holes CT1B, CT2B, and CT3B in the transistor according to the first embodiment of the present disclosure can be disposed in parallel to the width W of the overlap region between the active layer ACT and the gate electrode TG, as shown in FIG. 4.

In the transistor according to the first embodiment of the present disclosure, the first contact holes CT1A, CT2A, and CT3A and the second contact holes CT1B, CT2B, and CT3B can be disposed in parallel to the width W of the overlap region between the gate electrode TG and the active layer ACT, as shown in FIG. 4.

The reason why the first contact hole CT3A and the second contact hole CT3B have the greatest third width HW3 adjacent to the central portion C of the active layer ACT in the width (W) direction is to compensate for a diffusion deviation caused by a heat generation amount difference in the width (W) direction of the channel.

In the first embodiment of the present disclosure, the channel of the active layer ACT corresponds to the region overlapping with the gate electrode TG and, as such, the active layer ACT is provided with the channel having the width W and the length L. Since the channel is formed in the overlap region between the gate electrode TG and the active layer ACT, the channel is lengthily disposed in the width (W) direction of the active layer ACT.

The active layer ACT can be lengthily disposed in the width (W) direction, and the first and second source-drain electrodes SD1 and SD2 can also be lengthily disposed in the width (W) direction of the active layer ACT. In addition, the first and second source-drain electrodes SD1 and SD2 lengthily formed in the width (W) direction of the active layer ACT and the active layer ACT have a plurality of first contact holes CT1A, CT2A, and CT3A and a plurality of second contact holes CT1B, CT2B, and CT3B under the condition that the first contact holes CT1A, CT2A, and CT3A and the second contact holes CT1B, CT2B, and CT3B have different widths in different regions in the width (W) direction, respectively.

This will be described in detail hereinafter.

When a transistor, which has a channel with a wide width, is driven, generation of heat can be concentrated at a central portion of the channel in the width (W) direction. In the transistor having the wide-width channel, hydrogen can be diffused in an inside of the active layer ACT and from insulating layers including the gate insulating layer 125 adjacent to the active layer ACT due to heat, and the diffused hydrogen can cause expansion of a conductive region. As the width of the channel increases, hydrogen diffusion can increase. Due to diffusion of hydrogen, the conductive region is diffused toward the channel and, as such, heat is further concentrated at the central portion C of the overlap region between the gate electrode TG and the active layer ACT than at the edge portion E of the overlap region. As a result, a phenomenon in which an effective channel length Leff decreases can be deepened. That is, an effective channel length decrease ΔL of the transistor caused by generation of heat during driving of the transistor can become severe as the width of the transistor increases. As the channel extends from the edge portion E to the central portion C when viewed in the width direction of the channel, the heat generation amount increases. As a result, the effective length Leff of the channel can have a concave shape at a central portion thereof in the width direction when observed in a plan view.

In the transistor according to the first embodiment of the present disclosure, the first contact holes CT1A, CT2A, and CT3A and the second contact holes CT1B, CT2B, and CT3B, which function as hydrogen discharge paths, have widths HW1, HW2, and HW3 gradually increasing as the active layer ACT extends from the edge portion E to the central portion C, in order to prevent a variation in the effective length Leff of the channel among different regions.

In the transistor according to the first embodiment of the present disclosure, the first and second contact holes CT3A and CT3B having the greatest third width HW3 are disposed adjacent to the central portion C of the channel (the region of the active layer ACT overlapping with the gate electrode TG), and hydrogen is selectively discharged outwards through strong thermal treatment of the first and second contact holes CT3A and CT3B before the first and second source-drain electrodes SD1 and SD2 are connected to the active layer ACT through the first contact holes CT3A and CT3B. As surplus hydrogen in the active layer ACT or hydrogen remaining at insulating layers 125, 126, 127, and 124 adjacent to the active layer ACT is discharged outwards through execution of thermal treatment before connection of the first and second source-drain electrodes SD1 and SD2 to the active layer ACT, a cause of hydrogen diffusion occurring during driving of the transistor can be removed, and a decrease in the effective channel length Leff and deviations of the effective channel length Leff in different regions caused by hydrogen diffusion can be prevented.

In addition, in the transistor according to the first embodiment of the present disclosure, in addition to the contact holes CT3A and CT3B having the third width HW3, the contact holes CT2A and CT2B having the second width HW2 and the contact holes CT1A and CT1B having the first width HW1 can be used for hydrogen discharge through thermal treatment in the same process as that of the contact holes CT3A and CT3B before connection of the first and second source-drain electrodes SD1 and SD2 to the active layer ACT.

That is, the active layer ACT is provided with the contact holes CT3A and CT3B having the greatest third width HW3 at the central portion C thereof in the width (W) direction, is provided with the contact holes CT1A and CT1B having the smallest first width HW1 at the edge portion E thereof in the width (W) direction, and is provided with the contact holes CT2A and CT2B having the second width HW2 between the first width HW1 and the third width HW3 at a portion thereof between the central portion and the edge portion in the width (W) direction.

Meanwhile, the first contact holes CT1A, CT2A, and CT3A and the second contact holes CT1B, CT2B, and CT3B can be formed by forming a first interlayer insulating layer 126 and a second interlayer insulating layer 127 on the gate electrode TG, and selectively removing the second interlayer insulating layer 127, the first interlayer insulating layer 126, and the gate insulating layer 125 such that predetermined portions of the active layer ACT are exposed.

It can be possible to discharge hydrogen components outwards from the inside of the active layer ACT and from the first and second interlayer insulating layers 126 and 127 and the gate insulating layer 125 contacting side walls of the first contact holes CT1A, CT2A, and CT3A and the second contact holes CT1B, CT2B, and CT3B by performing thermal treatment at about 200 to 400° C. for 1 hour or more after exposure of the active layer ACT through the first contact holes CT1A, CT2A, and CT3A and the second contact holes CT1B, CT2B, and CT3B. In this case, the amount of hydrogen components discharged outwards through the first and second contact holes CT3A and CT3B having a relatively great area can be great.

Surplus hydrogen and residual hydrogen at the active layer ACT, the gate insulating layer 125 adjacent to the active layer ACT and the first and second interlayer insulating layers 126 and 127 adjacent to the active layer ACT can be discharged through the first contact holes CT1A, CT2A, and CT3A and the second contact holes CT1B, CT2B, and CT3B. Accordingly, hydrogen diffusion caused by different heat generation amounts in different regions during driving of the transistor after manufacture of the transistor can be preliminarily prevented.

Each of the first contact holes CT1A, CT2A, and CT3A and the second contact holes CT1B, CT2B, and CT3B, which is disposed in the same region at the first and second interlayer insulating layers 126 and 127 and the gate insulating layer 125 can be continuous at the plural layers.

The first and second interlayer insulating layers 126 and 127 can be formed as a single interlayer insulating layer.

When the gate insulating layer 125 and the first and second interlayer insulating layers 126 and 127 include different insulating materials, respectively, the first contact holes CT1A, CT2A, and CT3A and the second contact holes CT1B, CT2B, and CT3B can have slightly different diameters.

In the transistor according to the first embodiment of the present disclosure, the first contact holes CT1A, CT2A, and CT3A and the second contact holes CT1B, CT2B, and CT3B are spaced apart from the gate electrode TG by a first distance D1 while having different widths and different contact hole areas and, as such, can discharge different hydrogen amounts in accordance with the different contact hole areas.

As shown in FIGS. 4 to 6, a light shielding pattern BG can be further provided under the active layer ACT to shield light incident upon the active layer ACT from the bottom side of the substrate 111.

The light shielding pattern BG is electrically connected to the gate electrode TG. The gate electrode TG and the light shielding pattern BG can be disposed at upper and lower sides with respect to the active layer ACT, respectively, and, as such, can function as a dual gate. Electrical interconnection between the light shielding pattern BG and the gate electrode TG can be achieved through provision of a contact in a region not overlapping with the active layer ACT.

Hereinafter, a method of forming the transistor according to the embodiment of the present disclosure will be described with reference to FIGS. 4 to 6.

A first insulating layer 121 and a second insulating layer 122 are sequentially disposed on the substrate 111. The first insulating layer 121 and the second insulating layer 122 are disposed on the substrate 111 to prevent moisture or impurities such as charged particles, etc. penetrating through the substrate 111 from penetrating a structure on the substrate 111 and to perform a surface planarization function. The first and second insulating layers 121 and 122 can function as a kind of buffer layer.

For example, each of the first insulating layer 121 and the second insulating layer 122 can include one or more inorganic insulating layers selected from a silicon oxide (SiOₓ) layer, a silicon nitride (SiNₓ) layer, and a silicon oxynitride (SiOₓN_{y}) layer, or can include a multilayer structure in which the inorganic insulating layers illustratively described above are stacked.

The above-described first and second insulating layers 121 and 122 can be formed as a single insulating layer. When a hetero-type active layer is provided at another layer on the substrate 111, thereby constituting a hetero-type transistor, one of the first and second insulating layers 121 and 122 can be used as a gate insulating layer or a buffer layer of the active layer disposed nearest to the substrate 111.

The light shielding pattern BG is disposed on the second insulating layer 122. The light shielding pattern BG is disposed to correspond to a lower side of the active layer ACT formed over the light shielding pattern BG and, as such, can prevent external light incident from the side of the substrate 111 from influencing the active layer ACT.

For example, the second insulating layer 122 can be made of a conductive metal material. In detail, the conductive metal material can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). If necessary, when a hetero-type active layer is provided on the substrate 111, one of the active layers can be a layer treated to have conductivity, that is, a conductive layer.

A third insulating layer 123 and a fourth insulating layer 124 can be disposed on the second insulating layer 122 on which the light shielding pattern BG is disposed.

Each of the third and fourth insulating layers 123 and 124 includes an inorganic insulating layer. The third and fourth insulating layers 123 and 124 can be formed as a single insulating layer.

The active layer ACT is provided on the fourth insulating layer 124 while overlapping with the light shielding pattern B. The active layer ACT can have a shape which is long in the width (W) direction while being short in a longitudinal direction interesting the width (W) direction, as shown in FIG. 4.

The gate insulating layer 125 is provided on the active layer ACT.

When the active layer ACT is made of an oxide semiconductor, it can be possible to minimize a reduction in reliability of the active layer ACT disposed adjacent to the fourth insulating layer 124 and the gate insulting layer 125 due to hydrogen particles because each of the fourth insulating layer 124 and the gate insulating layer 125 does discharge a small amount of hydrogen particles during thermal treatment, etc. in the manufacturing process when each of the fourth insulating layer 124 and the gate insulating layer 125 is constituted by a silicon oxide layer.

The gate electrode TG, which extends in the width (W) direction of the active layer ACT and has the overlap region having the length L and the width W, as shown in FIG. 4, is disposed on the gate insulating layer 125.

The gate electrode TG is formed of, for example, a conductive metal material. The conductive metal material can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

After formation of the gate electrode TG, the active layer ACT is doped with impurity ions in a region disposed outside the gate electrode G, using at least the gate electrode G as a mask, thereby forming a conductive region. The conductive region formed through doping with impurity ions using the gate electrode TG as a mask can be a region of the active layer ACT except for the region overlapping with the gate electrode TG. The conductive region can minimize resistance of contact portions of the first and second source-drain electrodes SD1 and SD2 when the conductive region subsequently contacts the conductive metal of the first and second source-drain electrodes SD1 and SD2. Referring to FIG. 5, the region of the active layer ACT overlapping with the gate electrode TG (the region corresponding to “L”) is an intrinsic region, which is a region not doped with impurities, and, as such, can function as the channel C. The region of the active layer ACT not overlapping with the gate electrode TG can be a doped region DP, that is, a conductive region.

The first and second interlayer insulating layers 126 and 127 are sequentially disposed on the gate insulating layer 125 on which the gate electrode TG is disposed.

The second interlayer insulating layer 127, the first interlayer insulating layer 126, and the gate insulating layer 125 are selectively removed to expose predetermined portions of the conductive region (or doped region) DP of the active layer ACT, thereby forming the first contact holes CT1A, CT2A and CT3A and the second contact holes CT1B, CT2B and CT3B. As shown in FIG. 4, the first contact holes CT1A, CT2A and CT3A and the second contact holes CT1B, CT2B and CT3B have the greatest width HW3 at the central portion C of the active layer ACT in the width (W) direction and the smallest width HW1 at the edge portion E of the active layer ACT in the width (W) direction.

In the transistor according to the first embodiment of the present disclosure, the first contact holes CT1A, CT2A and CT3A and the second contact holes CT1B, CT2B and CT3B are spaced apart from the gate electrode TG by the first distance D1 while having different widths and different contact hole areas, respectively. As such, the first contact holes CT1A, CT2A and CT3A and the second contact holes CT1B, CT2B and CT3B can discharge different amounts of hydrogen in accordance with area differences.

Thermal treatment of the substrate 111 is performed at a temperature of 200 to 400° C. for 1 hour or more, and, as such, hydrogen remaining at the active layer ACT and the insulating layers 125, 126, 127, and 124 adjacent to the active layer ACT is discharged outwards through the first contact holes CT1A, CT2A and CT3A and the second contact holes CT1B, CT2B and CT3B.

Thereafter, a metal material is formed to fill the first contact holes CT1A, CT2A and CT3A and the second contact holes CT1B, CT2B and CT3B, and is then selectively removed to form the first source drain electrode SD1 connected to the active layer ACT through the first contact holes CT1A, CT2A and CT3A and the second source-drain electrode SD2 connected to the active layer ACT through the second contact holes CT1B, CT2B and CT3B.

One of the first source-drain electrode SD1 and the second source-drain electrode SD2 can function as a source electrode of the transistor, and the other of the first source-drain electrode SD1 and the second source-drain electrode SD2 can function as a drain electrode of the transistor.

When the gate insulating layer 125 and the first and second interlayer insulating layers 126 and 127 include different insulating materials, respectively, the first contact holes CT1A, CT2A, and CT3A and the second contact holes CT1B, CT2B, and CT3B can have slightly different diameters.

The first and second interlayer insulating layers 126 and 127 can be formed as a single interlayer insulating layer.

In the transistor according to the first embodiment of the present disclosure, the first contact holes CT1A, CT2A, and CT3A and the second contact holes CT1B, CT2B, and CT3B function as hydrogen discharge paths during execution of the manufacturing process. In addition, the first contact holes CT1A, CT2A, and CT3A and the second contact holes CT1B, CT2B, and CT3B have a greatest width at the central portion C of the active layer ACT in the width (W) direction of the active layer ACT while having a smallest width at the edge portion E of the active layer ACT in the width (W) direction. Accordingly, the removal amount of surplus hydrogen is increased as the active layer ACT extends from the edge portion E to the central portion C in the width (W) direction and, as such, it can be possible to prevent or minimize expansion of the conductive region and a decrease in effective channel length caused by hydrogen diffusion even when a heat generation amount at the central portion C of the active layer ACT is great during driving of the transistor. Accordingly, deviations of effective channel length of the active layer in different regions can be prevented.

As shown in FIGS. 4 to 6, the transistor according to the first embodiment of the present disclosure can be provided at a gate-in-panel (GIP) and has a wide-width channel and, as such, can be used as a high-current output element. In this case, the first contact holes CT1A, CT2A, and CT3A and the second contact holes CT1B, CT2B, and CT3B can function as hydrogen discharge paths during execution of the manufacturing process and, as such, can rapidly discharge hydrogen in the width direction of the wide-width channel, thereby effectively preventing influence of hydrogen diffusion.

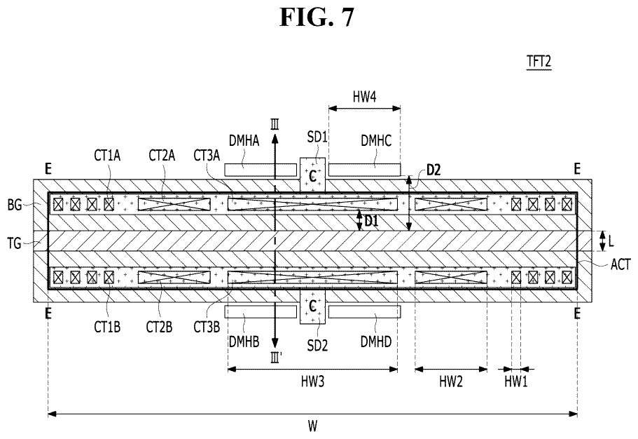

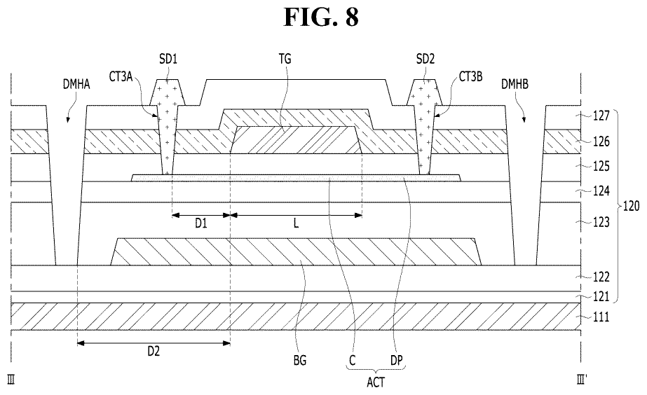

FIG. 7 is a plan view showing a transistor according to a second embodiment of the present disclosure. FIG. 8 is a cross-sectional view taken along line III-III′ in FIG. 7.

As shown in FIGS. 7 and 8, the transistor according to the second embodiment of the present disclosure further includes dummy holes DMHA, DMHB, DMHC, and DMHD at insulating layers 120 outside the active layer ACT as a second group of hydrogen discharge paths in addition to the first contact holes CT1A, CT2A, and CT3A and the second contact holes CT1B, CT2B, and CT3B as a first group of hydrogen discharge paths.

The dummy holes DMHA, DMHB, DMHC, and DMHD are disposed outside the active layer ACT while being adjacent to the central portion C of the active layer ACT in the width (W) direction, and cope with a great heat generation amount at the central portion C of the active layer ACT in the width (W) direction during driving of the transistor.

In addition, the dummy holes DMHA, DMHB, DMHC, and DMHD are also formed at the third and fourth insulating layers 123 and 124, differently from the first contact holes CT1A, CT2A, and CT3A and the second contact holes CT1B, CT2B, and CT3B provided at the gate insulating layer 125 and the first and second interlayer insulating layers 126 and 127. The dummy holes DMHA, DMHB, DMHC, and DMHD are formed to have a structure extending to a greater depth through the insulating layers than that of the first contact holes CT1A, CT2A, and CT3A and the second contact holes CT1B, CT2B, and CT3B and, as such, can effectively discharge hydrogen from the insulating layers 120 (123, 124, 125, 126, and 127) therearound.

In this case, it can be possible to discharge residual hydrogen included in the third and fourth insulating layers 123 and 124 under the active layer ACT, thereby effectively preventing hydrogen diffusion at the central portion C of the active layer ACT in the width (W) direction.

If necessary or desirable, the dummy holes DMHA, DMHB, DMHC, and DMHD can be further formed at the first and second insulating layers 121 and 122.

The first contact holes CT1A, CT2A, and CT3A and the second contact holes CT1B, CT2B, and CT3A are spaced apart from the gate electrode TG by the first distance D1.

The dummy holes DMHA, DMHB, DMHC, and DMHD are spaced apart from the gate electrode TG by a second distance D2. The second distance D2 is greater than the first distance D1 and, as such, the first contact holes CT1A, CT2A, and CT3A and the second contact holes CT1B, CT2B, and CT3A more effectively discharge residual hydrogen included in the active layer ACT, and the dummy holes DMHA, DMHB, DMHC, and DMHD effectively discharge residual hydrogen included in the insulating layers 120 around the active layer ACT.

The dummy holes DMHA, DMHB, DMHC, and DMHD may not overlap with the active layer ACT.

The dummy holes DMHA, DMHB, DMHC, and DMHD can be formed together with the first contact holes CT1A, CT2A, and CT3A and the second contact holes CT1B, CT2B, and CT3A when the first contact holes CT1A, CT2A, and CT3A and the second contact holes CT1B, CT2B, and CT3A are formed.

Discharge of hydrogen gas from the dummy holes DMHA, DMHB, DMHC, and DMHD, the first contact holes CT1A, CT2A, and CT3A, and the second contact holes CT1B, CT2B can be simultaneously carried out through the same thermal treatment.

The dummy holes DMHA, DMHB, DMHC, and DMHD can be provided not only in a region adjacent to the central portion C of the active layer ACT in the width (W) direction, but also in a region adjacent to a region of the active layer ACT between the central portion C and the edge portion E and a region adjacent to the edge portion E. In this case, the dummy hole adjacent to the edge portion E of the active layer ACT in the width (W) direction can have a smaller width than that of the dummy hole provided adjacent to the central portion C of the active layer ACT in the width (W) direction, in order to prevent heat diffusion deviation generated during driving of the transistor.

The transistor according to the second embodiment of the present disclosure can be provided at a gate-in-panel (GIP) and has a wide-width channel and, as such, can be used as a high-current output element. In this case, the dummy holes DMHA, DMHB, DMHC, and DMHD can function as hydrogen discharge paths during execution of the manufacturing process, together with the first contact holes CT1A, CT2A, and CT3A and the second contact holes CT1B, CT2B, and CT3B, and, as such, can rapidly discharge hydrogen in the width direction of the wide-width channel, thereby more effectively preventing influence of hydrogen diffusion.

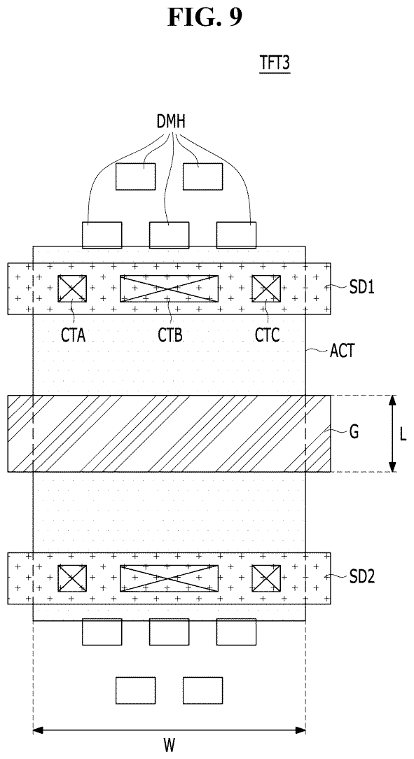

FIG. 9 is a plan view showing a transistor according to a third embodiment of the present disclosure.

As shown in FIG. 9, the transistor according to the third embodiment of the present disclosure includes an active layer ACT, a gate electrode G having a region overlapping with the active layer ACT, and a gate insulating layer (cf. “125” in FIG. 5) disposed between the active layer ACT and the gate electrode G.

Further, the transistor according to the third embodiment of the present disclosure, the gate electrode T and the active layer ACT have an overlap region having a width W and a length L. The transistor can include first and second source-drain electrodes SD1 and SD2.

Each of the first and second source-drain electrodes SD1 and SD2 includes a plurality of contact holes CTA, CTB, and CTC in an overlap region thereof with the active layer ACT. The plurality of contact holes CTA, CTB, and CTC have a greatest width at a central portion of the active layer ACT in a width (W) direction while having a small width at an edge portion of the active layer ACT in the width (W) direction.

In addition, the transistor according to the third embodiment of the present disclosure includes the contact holes CTA, CTB, and CTC between the active layer ACT and the first and second source drain electrodes SD1 and SD2 as a first group of hydrogen discharge paths, and dummy holes DMH as a second group of hydrogen discharge paths.

The transistor according to the third embodiment of the present disclosure has a difference from the transistor according to the second embodiment of the present disclosure in that the dummy holes DMH are disposed in a plurality of rows adjacent to the first and second source drain electrodes SD1 and SD2.

In this case, a part of the dummy holes DMH has a portion overlapping with the edge portion of the active layer ACT and, as such, can achieve direct hydrogen discharge from the edge portion of the active layer ACT.

Moreover, the dummy holes DMH are disposed at a higher density at the central portion of the active layer ACT in the width (W) direction and, as such, effectively distribute and dissipate heat generated at the central portion of the active layer ACT in the width (W) direction and previously discharge hydrogen outwards, and, as such, prevent expansion of a conductive region caused by hydrogen diffusion from being deepened at the central portion of the active layer ACT in the width (W) direction, thereby preventing or minimizing effective length deviations in different regions of the active layer ACT.

Meanwhile, an example in which the transistor according to the third embodiment of the present disclosure includes a configuration having no light shielding pattern under the active layer ACT has been illustrated in FIG. 9. However, the transistor according to the embodiment of the present disclosure is not limited to the above-described conditions, and a light shielding pattern can be further provided under the active layer ACT to prevent the active layer ACT from being influenced by light incident from a bottom side of a substrate. In addition, the light shielding pattern can also be electrically connected to the gate electrode G and, as such, can function as a dual gate.

Each transistor according to the embodiments of the present disclosure can previously discharge hydrogen outwards through a configuration of contact holes or dummy holes and, as such, can prevent a problem resulting from expansion of the conductive region occurring as hydrogen remaining at the active layer and the insulating layer is diffused due to heat generated in a process or during driving of the transistor.

In addition, each transistor according to the embodiments of the present disclosure can prevent or minimize doping diffusion deepened at a central portion of a transistor structure having a wide-width channel by disposing hydrogen discharge paths to have different sizes in a width direction of an active layer in a structure in which the active layer overlaps with a gate electrode at a wide width and a channel is defined. That is, a hydrogen diffusion amount difference caused by a heat generation amount difference among different regions can be compensated for by a size difference of hydrogen discharge paths and, as such, it can be possible to maintain effective channel lengths in a width direction to be equal or similar. Accordingly, it can be possible to prevent an effective channel length from decreasing abruptly at the central portion of the transistor in the width direction.

Meanwhile, a transistor having no hydrogen discharge path has a tendency toward deepening of an effective channel length decrease ΔL caused by hydrogen diffusion occurring during driving of the transistor when the width of an active layer increases. In addition, deepening of the effective channel length decrease means a decrease in an effective channel length Leff, and the transistor having the decreased effective channel length exhibits a tendency toward threshold voltage shift in a negative direction.

Each transistor according to the embodiments of the present disclosure can reduce or minimize channel length deviations in different regions in a structure having a wide-width channel, thereby preventing a channel length variation proportional to a width increase and reducing width sensitivity. In this regard, a stable wide-width transistor can be realized. Accordingly, an active layer can have a length margin, taking into consideration a decrease in effective channel length and, as such, it is unnecessary to form the active layer to have a large size. Thus, a narrow bezel can be realized.

In each transistors according to the embodiments of the present disclosure, it can be possible to reduce or minimize influence of hydrogen diffusion occurring after a contact hole formation process by removing hydrogen in not only an active layer, but also in an insulating layer adjacent to the active layer, through first group of hydrogen discharge paths configured to expose a conductive region of the active layer and second group of hydrogen discharge paths formed in the insulating layer, outside the active layer, by thermal treatment.

In the transistor according to the embodiment of the present disclosure, hydrogen discharge paths can be formed together with contact holes in a contact hole formation process, without addition of a separate process. Accordingly, it can be possible to reduce use amounts of materials used in the overall manufacturing process, such as a deposition material, an etchant, etc. required upon addition of a separate process in the transistor and a display device including the transistor. It can be possible to provide a display device including a transistor capable of reducing generation of greenhouse gases due to a manufacturing process.

In addition, since the active layer can be designed to minimize a margin, a wide-width transistor can be realized. Accordingly, it can be possible to reduce production energy, to reduce generation of hazardous materials and to reduce the weight of a display device including the transistor.

The display device according to the embodiment of the present disclosure has an advantage in that power consumption can be reduced, through application, thereto, of a high-power wide-channel transistor having a small size while being capable of controlling a variation in effective channel length and reducing threshold voltage sensitivity. Accordingly, there are environmental and social-sustainability advantages and, as such, environmental/social/governance (ESG) goals can be achieved.

Hereinafter, a display device in which the above-described hydrogen discharge paths are applied to a transistor will be described.

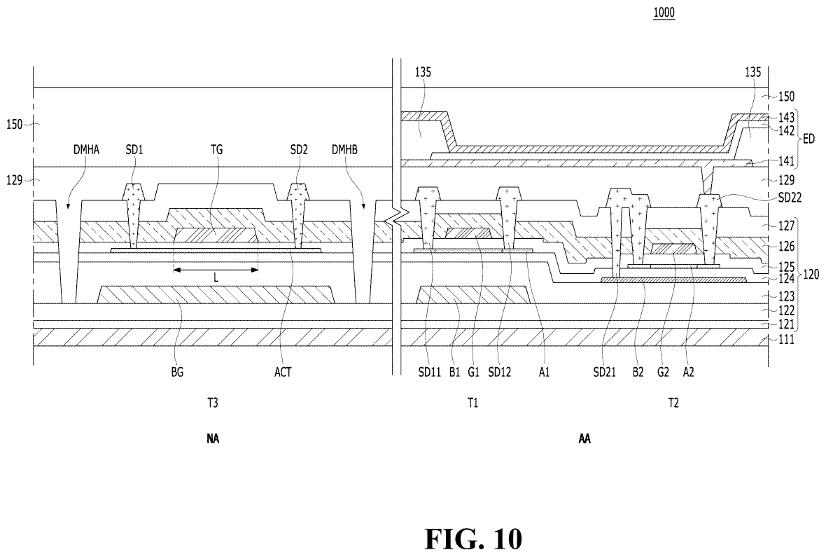

FIG. 10 is a cross-sectional view showing a display device according to one or more embodiments of the present disclosure.

As shown in FIG. 10, a substrate 111 includes an active area AA and a non-active area NA.

The active area AA is an area in which a sub-pixel SP described with reference to FIG. 1 is disposed. In the non-active area NA, a driver such as a gate-in-panel (GIP) or the like is disposed. The non-active area NA can surround the active area AA entirely or only in part(s).

The substrate 111 can be formed of a plastic material having flexibility and, as such, can have flexible characteristics. For example, the substrate 111 can be constituted by first and second organic layers overlapping each other under the condition that an inorganic interlayer insulating layer is interposed therebetween. Each of the first and second organic layers can include organic films of the same kind or different kinds made of, for example, polyethylene terephthalate (PET), polyimide, or the like. If necessary, an adhesive film made of, for example, a pressure sensitive adhesive (PSA), can be included between the first and second organic layers.

In another example, the substrate 111 can include a glass material having flexibility while having a small thickness.

The substrate 111 functions to support and protect constituent elements of a display device 1000 disposed thereon.

In the active area AA of the substrate 111, a first transistor T1 connected to a gate line (e.g., “GL” in FIG. 1) and a data line (e.g., “DL” in FIG. 1) and a second transistor T2 electrically connected to a light emitting element ED can be included. The first and second transistors T1 and T2 can have a direct interconnection relation. If necessary, the first and second transistors T1 and T2 can be interconnected under the condition that a part of the configuration of a compensation circuit is included therebetween. For example, the first transistor T1 can be a switching transistor, and the second transistor T2 can be a driving transistor.

In the non-active area NA of the substrate 111, a third transistor T3 can be included. For example, the third transistor T3 can be included in the gate-in-panel (GIP), and can be a buffer transistor having high power. When the third transistor T3 is included in the gate-in-panel (GIP), the third transistor T3 has an electrical connection relation to the gate line GL and, as such, can supply a gate voltage signal.

A plurality of stacked insulating layers 120 (121, 122, 123, 124, 125, 126, and 127) can be disposed on the active area AA and the non-active area NA of the substrate 111 to insulate electrodes BG, B1, B2, TG, G1, G2, SD1, SD2, SD11, SD12, SD21, and SD22 and active layers ACT, A1, and A2 constituting the first to third transistors T1, T2, and T3 from one another. The insulating layers 120 can include a first insulating layer 121, a second insulating layer 122, a third insulating layer 123, a fourth insulating layer 124, a gate insulating layer 125, a first interlayer insulating layer 126, and a second interlayer insulating layer 127.

In a portion of the active area AA or the non-active area NA of the substrate 111, a transistor having an active layer provided at another layer can be included in addition to the shown first to third transistors T1, T2, and T3. At least one of the first to fourth insulating layers 121, 122, 123, and 124 can function as a buffer layer or an interlayer insulating layer of the active layer other than the active layers ACT, A1, and A2 of the first to third transistors T1, T2, and T3, for example, an active layer including polysilicon.

The first insulating layer 121 is disposed on the active area AA and the non-active area NA of the substrate 111. The first insulating layer 121 can be called a buffer layer, and can have the same function as a buffer layer known in technical fields. The first insulating layer 121 can be disposed on the substrate 111 to protect structures disposed over the substrate 111 from moisture penetrating through the substrate 111 and to planarize a surface of the substrate 111.

The first insulating layer 121 can be disposed to extend to an edge portion of the substrate 111 and, as such, can prevent moisture from penetrating through an edge of the substrate 111. The first insulating layer 121 can be a single inorganic layer or can be constituted by a plurality of inorganic layers stacked alternately.

For example, the first insulating layer 121 can include one or more inorganic layers selected from a silicon oxide (SiOₓ) layer, a silicon nitride (SiNₓ) layer, and a silicon oxynitride (SiOₓN_{y}) layer or can include a multilayer structure in which the inorganic insulating layers illustratively described above are stacked.

The second insulating layer 122 can be disposed on the first insulating layer 121. The second insulating layer 122 can function as, for example, a second buffer layer. In this case, a part of the transistors included in the sub-pixel can include a polysilicon semiconductor layer, and the second insulating layer 122 can be disposed under the polysilicon semiconductor layer. The second insulating layer 122 can include an inorganic layer, for example, a silicon oxide (SiOₓ) layer, a silicon nitride (SiNₓ) layer, or a multilayer structure thereof. If necessary, the second insulating layer 122 can be used as a gate insulating layer of the transistor including the polysilicon semiconductor layer.

A light shielding pattern BG and a first light shielding pattern B1, which are made of a conductive metal material, can be provided on the second insulating layer 122 in the non-active area NA and the active area AA, respectively. In detail, the conductive metal material can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

The first light shielding pattern B1 can constitute one electrode of a storage capacitor included in the sub-pixel.

The third insulating layer 123 can be disposed on the second insulating layer 122 on which the light shielding pattern BG and the first light shielding pattern B1 are disposed. The third insulating layer 123 can function as an insulator of the storage capacitor connected to at least one of the first to third transistors T1, T2, and T3. Alternatively, the third insulating layer 123 can function as an interlayer insulating layer of the transistor including the polysilicon semiconductor layer.

The third insulating layer 123 can include an inorganic material. The inorganic material can include, for example, a silicon nitride (SiNₓ) layer.

A second light shielding pattern B2 made of a conductive metal material is disposed on the third insulating layer 123. In detail, the conductive metal material can include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti).

Each of the light shielding pattern BG and the first and second light shielding patterns B1 and B2 can be the same layer as the storage capacitor or first and second electrodes of the capacitor. Each of the light shielding pattern BG and the first and second light shielding patterns B1 and B2 can have a single-layer structure or a multilayer structure in which a plurality of different metal materials is stacked.

The fourth insulating layer 124 can be disposed on the third insulating layer 123 provided with the second light shielding pattern B2. The fourth insulating layer 124 can be disposed under the first and second active layers A1 and A2, and can function as a buffer layer. The fourth insulating layer 124 can function to planarize a surface of a region where the active layer ACT and the first and second active layers A1 and A2 disposed on the fourth insulating layer 124 are formed.

The fourth insulating layer 124 can include an inorganic material. For example, the inorganic material can include a silicon oxide (SiOₓ) layer or can include a multilayer structure in which inorganic layers are stacked.

The active layer ACT and the first and second active layers A1 and A2 are disposed on the fourth insulating layer 124. The active layer ACT and the first and second active layers A1 and A2 can include, for example, an oxide semiconductor material. The oxide semiconductor material can be constituted by a combination of at least one metal of zinc (Zn), indium (In), gallium (Ga), tin (Sn), and titanium (Ti) with an oxide. If necessary, a metal having high conductivity, such as iron (Fe) or the like, can be further included in the oxide semiconductor material to increase mobility. In an embodiment of the present disclosure, at least one of the active layer ACT and the first and second active layers A1 and A2 can have mobility different from those of the remaining ones of the active layer ACT and the first and second active layers A1 and A2 such that the active layer ACT and the first and second active layers A1 and A2 correspond to response times of respective transistors. For example, the active layer ACT of the third transistor T3 in the non-active area NA and the first active layer A1 of the first transistor T1 in the active area AA can have higher mobility than that of the active layer A2.

In more detail, the oxide semiconductor material constituting the active layer ACT and the first and second active layers A1 and A2 can include, for example, zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), iron-indium-zinc oxide (FIZO), or the like. When the active layer ACT and the first and second active layers A1 and A2 have different mobilities, respectively, the active layer ACT and the first and second active layers A1 and A2 can have different metal components included in respective oxides thereof or can have different content ratios of a plurality of metal components thereof.

The gate insulating layer 125 is disposed to cover the active layer ACT, the first active layer A1, and the second active layer A2.

A gate electrode TG, a first gate electrode G1, and a second gate electrode G2 are disposed on the gate insulating layer 125 to partially overlap with the active layer ACT, the first active layer A1, and the second active layer A2, respectively. The gate electrode TG, the first gate electrode G1, and the second gate electrode G2 can include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Each of the gate electrode TG, the first gate electrode G1, and the second gate electrode G2 can be constituted by a single layer or multiple layers.

The first gate electrode G1 can be connected to, for example, the gate line GL described with reference to FIG. 1.

In an embodiment of the present disclosure, the gate electrode TG and the first gate electrode G1 are connected to the light shielding pattern BG and the first light shielding pattern B1 disposed thereunder, respectively, and, as such, gate voltage signals having the same potential can be applied to the gate electrode TG and the first gate electrode G1, respectively. In this case, high-speed operation can be possible at a small size in accordance with potential stability of the light shielding pattern BG and the first light shielding pattern B1 and application of a dual gate structure of the third transistor T3 and the first transistor T1.

After formation of the gate electrode TG and the first and second gate electrodes G1 and G2, the active layer ACT, the first active layer A1, and the second active layer A2 are doped with impurities, thereby forming conductive regions. The active layer ACT, the first active layer A1, and the second active layer A2 can have channels in regions overlapping with the gate electrode TG and the first and second gate electrodes G1 and G2, respectively, and can have conductive regions doped with impurities in regions beyond the gate electrode TG and the first and second gate electrodes G1 and G2, respectively.

A first interlayer insulating layer 126 and a second insulating layer 127 are disposed on the gate insulating layer 125 on which the gate electrode TG and the first and second gate electrodes G1 and G2 are disposed.

The first interlayer insulating layer 126 and the second interlayer insulating layer 127 can be formed of an inorganic insulating material, and can have a single-layer structure, if necessary or if desirable.

For example, the first interlayer insulating layer 126 and the second interlayer insulating layer 127 can include a silicon oxide (SiOₓ) layer or a silicon nitride (SiNₓ) layer or can include a multilayer structure in which inorganic layers are stacked.

At least the second interlayer insulating layer 127, the first interlayer insulating layer 126 and the gate insulating layer 125 among the insulating layers 120 are selectively removed, thereby forming contact holes (e.g., cf. “CT1A”, “CT1B”, “CT2A”, “CT2B”, “CT3A”, and “CT3B” in FIGS. 4 to 8), through which doped regions DP of the active layer ACT, the first active layer A1, and the second active layer A2 are exposed, and forming dummy holes (e.g., cf. “DMHA”, “DMHB”, “DMHC”, and “DMHD” in FIG. 8) at an outside of the active layer ACT.

In this case, the dummy holes DMHA, DMHB, DMHC, and DMHD are formed to be deeper than the contact holes CT1A, CT1B, CT2A, CT2B, CT3A, and CT3B and, as such, have removal portions of the third and fourth insulating layers 123 and 124.

Thermal treatment at a high temperature is performed for 1 hour or more in a state in which the contact holes CT1A, CT1B, CT2A, CT2B, CT3A, and CT3B and the dummy holes DMHA, DMHB, DMHC, and DMHD are exposed, thereby outwardly discharging movable hydrogen ions included in the active layer ACT and the insulating layers 120.

After discharge of hydrogen ions, a metal material is formed on the second interlayer insulating layer 126. The metal material is then selectively removed, thereby forming first to sixth source-drain electrodes SD1, SD2, SD11, SD12, SD21, and SD22 connected to the active layer ACT, the first active layer A1, and the second active layer A2 through the contact holes CT1A, CT1B, CT2A, CT2B, CT3A, and CT3B.

Through the contact holes CT1A, CT1B, CT2A, CT2B, CT3A, and CT3B, the first source-drain electrode SD1 and the second source-drain electrode SD2 can be connected to the active layer ACT, the third source-drain electrode SD11 and the fourth source-drain electrode SD12 can be connected to the first active layer A1, and the fifth source-drain electrode SD21 and the sixth source-drain electrode SD22 can be connected to the second active layer A2.

The first to sixth source-drain electrodes SD1, SD2, SD11, SD12, SD21, and SD22 can include at least one of an aluminum-based metal such as aluminum (Al) or an aluminum alloy, a copper-based metal such as copper (Cu) or a copper alloy, a molybdenum-based metal such as molybdenum (Mo) or a molybdenum alloy, chromium (Cr), tantalum (Ta), neodymium (Nd), and titanium (Ti). Each of the first gate electrode G1 and the second gate electrode G2 can be constituted by a single layer or multiple layers.

The sixth source-drain electrode SD21 is connected to the second light shielding pattern B2 disposed under the second active layer A2 while being formed to further extend from one side of the second active layer A2, and can stabilize the potential of the second light shielding pattern B2.

The first transistor T1 includes, on the substrate 111, the first light shielding pattern B1, the first active layer A1 overlapping with the first light shielding pattern B1, the first gate electrode G1 overlapping with the intrinsic region of the first active layer A1, and the third source-drain electrode SD11 and the fourth source-drain electrode SD12 connected to the doped regions DP of the first active layer A1 disposed at opposite sides of the first gate electrode G1.

The second transistor T2 includes, on the substrate 111, the second light shielding pattern B2, the second active layer A2 overlapping with the second light shielding pattern B2, the second gate electrode G2 overlapping with the intrinsic region (UDP) of the second active layer A2, and the fifth source-drain electrode SD21 and the sixth source-drain electrode SD22 connected to the doped regions DP of the second active layer A2 disposed at opposite sides of the second gate electrode G2.

The third transistor T3 includes, on the substrate 111, the light shielding pattern BG, the active layer ACT overlapping with the light shielding pattern BG, the gate electrode TG overlapping with the intrinsic region (UDP) of the active layer ACT, and the first source-drain electrode SD1 and the second source-drain electrode SD2 connected to the doped regions DP of the active layer ACT disposed at opposite sides of the gate electrode TG.

A planarization layer 129 can be provided on the first to sixth source-drain electrodes SD1, SD2, SD11, SD12, SD21, and SD22, for protection of the first to third transistors T1, T2 and T3.

The planarization layer 129 can include an organic material. The organic material can include one or more of acryl resin, phenolic resin, polyimide resin, unsaturated polyester resin, polyamide resin, benzocyclobutene, polyphenylene resin, and polyphenylene sulfide resin. The planarization layer 129 can be provided over a region of the third transistor T3 in which the dummy holes DMHA, DMHB, DMHC, and DMHD are included. The planarization layer 129 fills the dummy holes DMHA, DMHB, DMHC, and DMHD, thereby preventing the insulating layers 120 from being exposed at side portions of the dummy holes DMHA, DMHB, DMHC, and DMHD and, as such, protecting the insulating layers 120. When the depths of the dummy holes DMHA, DMHB, DMHC, and DMHD are greater than the thickness of the planarization layer 129, an encapsulation layer 150 can be partially introduced in the dummy holes DMHA, DMHB, DMHC, and DMHD.

An anode 141 can be further provided on the planarization layer 129. The anode 141 can be connected to the sixth source-drain electrode SD22 through a contact hole in the planarization layer 129. The anode 141, a cathode 143 facing the anode 141, and an intermediate layer 142 between the anode 141 and the cathode 143 constitute the light emitting element ED.

One of the anode 141 and the cathode 143 can include a reflective electrode, and the other of the anode 141 and the cathode 143 can include a transparent electrode or a reflective transmissive electrode.

When the anode 141 includes a reflective electrode, the anode 141 can function to shield light incident upon the transistor TFT disposed thereunder. The anode 141 can be constituted by, for example, a stack structure of a first transparent electrode, a reflective electrode, and a second transparent electrode. The second transparent electrode, which is an uppermost electrode of the anode 141, is made of a dielectric material and, as such, can lower a hole injection barrier at an interface thereof with the intermediate layer 142. In this case, each of the first and second transparent electrode can be a transparent oxide electrode such as ITO, IZO, or the like. The reflective electrode can include silver, a silver alloy such as Ag—Pd—Cu (APC), aluminum, or an aluminum alloy.

For example, the anode 141 can be formed to have a multilayer structure such as a stack structure of aluminum (Al) and titanium (Ti) (Ti/Al/Ti), a stack structure of aluminum (Al) and ITO (ITO/Al/ITO), a stack structure of an Ag—Pd—Cu (APC) alloy and ITO (ITO/APC/ITO), a stack structure of silver (Ag) and a molybdenum-titanium alloy (Ag/MoTi), or can include a single-layer structure constituted by one of silver (Ag), aluminum (Al), molybdenum (Mo), gold (Au), magnesium (Mg), calcium (Ca), and barium (Ba), or an alloy of two or more thereof.

A pixel definition layer 135 is disposed to surround an edge of the anode 141. An emission region can be defined by an opened region of the pixel definition layer 135. The pixel definition layer 135 can extend to the non-active area Na, and can have a portion at least partially overlapping with the gate-in-panel (GIP).

The pixel definition layer 135 can include an inorganic material or an organic material. The pixel definition layer 135 can include an opaque material (for example, a black material) in order to prevent light interference between adjacent sub-pixels SP. In this case, the pixel definition layer 135 can include a light shielding material constituted by at least one of a color pigment, organic black, and carbon.

The intermediate layer 142 can include a hole injection layer, a hole transport layer, an emission layer, an electron transport layer, an electron injection layer, etc. The intermediate layer 142 can be formed to have a tandem structure including a plurality of stacks each including a hole transport layer, an emission layer, and an electron transport layer under the condition that a charge generation layer is disposed between adjacent ones of the stacks. The charge generation layer can include, for example, an n-type charge generation layer and a p-type charge generation layer.

The emission layer included in the intermediate layer 142 can be configured such that emission layers are different at different sub-pixels, respectively. The emission layer (EL) can be constituted by a red emission layer configured to emit red light, a green emission layer configured to green light, or a blue emission layer configured to blue light. The red emission layer, the green emission layer, and the blue emission layer can be disposed on the anode 141 at different sub-pixels SP, respectively.

For example, the red emission layer can be disposed at a red sub-pixel in a patterned state, the green emission layer can be disposed at a green sub-pixel in a patterned state, and the blue emission layer can be disposed at a blue sub-pixel in a patterned state. However, embodiments of the present disclosure are not limited to the above-described conditions, and at least two organic emission layers of the red emission layer, the green emission layer, and the blue emission layer can be disposed at one sub-pixel SP in a stacked state.

If necessary or desirable, the emission layer can be a white emission layer configured to emit white light. In this case, the emission layer (EL) may not take the form of a pattern at sub-pixels SP, but can take the form of a common layer disposed at sub-pixels SP in common while including one or more layers.

As described above, the intermediate layer 142 can be disposed to have a tandem structure of two or more stacks. In this case, each light emitting element ED can include a charge generation layer disposed between adjacent ones of the stacks. The charge generation layer can be a common layer disposed at a top surface of the active area AA.

The cathode 143 can be formed by laminating a transmissive electrode made of, for example, ITO, IZO, or the like, or a reflective transmissive electrode made of, for example, silver, a silver alloy, magnesium, a magnesium alloy, ytterbium (Yb), an ytterbium alloy, or the like. In another embodiment, the cathode 143 can be partially removed from a transmissive area (TA) or can be formed to have a small thickness. The cathode 143 can be a common layer disposed at sub-pixels SP in common to apply the same voltage. To this end, the cathode 143 can be disposed to extend from the active area AA to a portion of the non-active area NA.

The cathode 143 can be a transmissive electrode. The cathode 143 can include a transparent conductive oxide (TCO) through which light can pass, such as ITO or IZO, or a semi-transmissive conductive material such as magnesium (Mg), silver (Ag), or an alloy of magnesium (Mg) and silver (Ag). When the cathode 143 is constituted by a semi-transmissive conductive material, light emission efficiency can be enhanced by virtue of the microcavity effect.

Heretofore, a top-emission type light emitting element has been described as the light emitting element ED. However, the light emitting element ED of the present disclosure is not limited to the above-described type, and can have a bottom-emission type in which light emitted from the intermediate layer 142 is discharged toward the substrate 111. In this case, the anode 141 can be constituted by a transparent or translucent electrode material, and the cathode 143 can be constituted by a reflective electrode material.

The encapsulation layer 150 is disposed on the light emitting element ED. The encapsulation layer 150 covers the active area AA and the non-active area NA and, as such, can prevent oxygen or moisture from penetrating the light emitting element ED. If necessary, other layers such as a capping layer, etc. can be interposed between the encapsulation layer 150 and the cathode 143.

The encapsulation layer 150 can be constituted by a plurality of layers. The encapsulation layer 150 can be constituted by a structure in which an inorganic layer including an inorganic insulating material and an organic layer including an organic insulating material are alternately stacked. For example, the inorganic insulating material can include one or more materials such as silicon oxide, silicon nitride and/or silicon oxynitride, etc.

The organic insulating material can include one or more materials selected from the group consisting of polyethylene terephthalate, polyethylene naphthalate, polycarbonate, polyimide, polyethylene sulfonate, polyoxymethylene, polyarylate, and hexamethyldisiloxane.

A capping layer can be further formed on the cathode 143 to protect the cathode 143 of the light emitting element ED and to enhance light discharge efficiency in an upward direction.

As shown in FIG. 10, the third transistor T3 in the non-active area NA has a configuration in which the contact holes CT3A, CT3B, CT2A, CT2B, CT1A, and CT1B having grater areas at the central portion of the active layer ACT in the width (W) direction than at the edge portion of the active layer ACT in the width (W) direction are disposed, and the dummy holes DMHA, DMHB, DMHC, and DMHD are disposed outside the active layer ACT. Accordingly, when hydrogen is forcibly discharged outwards before connection of the first and second source-drain electrodes SD1 and SD2 to the active layer ACT, hydrogen diffusion occurs hardly or is prevented even when heat is generated in the active layer ACT during driving of the third transistor T3 or there are heat generation amount differences among different regions. As a result, there is no or little variation in size of the conductive region after doping with impurities.

In addition, the configuration in which the contact holes CT3A, CT3B, CT2A, CT2B, CT1A, and CT1B have different areas in different regions in the width (W) direction of the active layer ACT, and the dummy holes DMHA, DMHB, DMHC, and DMHD are disposed outside the active layer ACT can also be applied to the first and second transistors T1 and T2.

Disposition of the contact holes CT3A, CT3B, CT2A, CT2B, CT1A, and CT1B in different regions in the width (W) direction of the active layer ACT in this order and/or provision of the dummy holes DMHA, DMHB, DMHC, and DMHD at an outside of the active layer ACT are more effective to prevent deviations of effective channel lengths in different regions in a transistor having a wide width.

For example, a buffer transistor of the gate-in-panel requires high output current in order to charge a desired voltage at a particular node within a short time, and is required to have a wide-width channel. When an active layer is provided using an oxide semiconductor layer, a width of about 100 μm or more can be required in order to realize high output current.

However, in a wide-width transistor having no hydrogen discharge path, a heat generation amount is great at a central portion of an active layer in a width direction and, as such, a decrease in effective channel length can be deepened. In each transistor according to the embodiments of the present disclosure, it can be possible to prevent or minimize diffusion of hydrogen during driving of the transistor through discharge of hydrogen according to thermal treatment before a source-drain electrode connection process in accordance with disposition of the contact holes CT3A, CT3B, CT2A, CT2B, CT1A, and CT1B in different regions in the width (W) direction of the active layer ACT in this order and/or provision of the dummy holes DMHA, DMHB, DMHC, and DMHD at an outside of the active layer ACT. Accordingly, it can be possible to prevent deviation of effective channel length variations at the central and edge portions of the active layers in the width direction, to prevent a variation in characteristics of the transistor caused by effective channel length variation, and to secure a uniform effective channel length in different regions. Thus, the wide-width transistor can be stably driven.

In addition, when the transistor according to the embodiment of the present disclosure is applied to a wide-width transistor provided in a non-active area or an active area, it can be possible to reduce width sensitivity of an active layer. Accordingly, freedom of design of a transistor having high power can be enhanced.

Each transistor according to the embodiments of the present disclosure can reduce or minimize channel length deviations in different regions in a structure having a wide-width channel, thereby preventing a channel length variation proportional to a width increase and reducing width sensitivity. In this regard, a stable wide-width transistor can be realized. Accordingly, an active layer can have a length margin, taking into consideration a decrease in effective channel length and, as such, it is unnecessary to form the active layer to have a large size. Thus, a narrow bezel can be realized.

In each transistor according to the embodiments of the present disclosure, it can be possible to reduce or minimize influence of hydrogen diffusion occurring after a contact hole formation process by removing hydrogen in not only an active layer, but also in an insulating layer adjacent to the active layer, through first hydrogen discharge paths configured to expose a conductive region of the active layer and second hydrogen discharge paths formed in the insulating layer, except for the active layer, by thermal treatment.

In the transistor according to the embodiment of the present disclosure, formation of holes for hydrogen discharge paths can be carried out together with formation of contact holes in a contact hole formation process. Accordingly, it can be possible to solve a problem such as hydrogen diffusion or the like without addition of a separate process. Accordingly, there is an advantage of process optimization.

In the transistor according to the embodiment of the present disclosure, hydrogen discharge paths can be formed together with contact holes in a contact hole formation process, without addition of a separate process. Accordingly, it can be possible to reduce use amounts of materials used in the overall manufacturing process, such as a deposition material, an etchant, etc. required upon addition of a separate process in the transistor and a display device including the transistor. It can be possible to provide a display device including a transistor capable of reducing greenhouse gases generated due to a manufacturing process.

In addition, in the display device including the transistor according to the embodiment of the present disclosure, the active layer can be designed to minimize a length margin thereof. Accordingly, in implementation of a wide-width transistor, it can be possible to reduce production energy, to reduce generation of hazardous materials and to reduce the weight of a display device including the transistor. The display device according to the embodiment of the present disclosure can enable application, thereto, of a high-power wide-channel transistor having a small size while being capable of controlling a variation in effective channel length and reducing threshold voltage sensitivity. Accordingly, in implementation of the wide-width transistor, it can be possible to minimize a channel length margin and, as such, the transistor can be driven using low power, as compared to a structure having a channel length margin.

Furthermore, the display device according to the embodiment of the present disclosure can be driven using low power while reducing power consumption thereof. Accordingly, there are environmental and social-sustainability advantages and, as such, environmental/social/governance (ESG) goals can be achieved.

A transistor according to one embodiment of the present disclosure can comprise an active layer, a gate electrode having a region overlapping with the active layer, a gate insulating layer disposed between the active layer and the gate electrode; and a plurality of holes in the gate insulating layer at an outside of an overlap area between the gate electrode and the active layer. A disposition density of the plurality of holes can be higher in a region adjacent to an edge of the active layer in a width direction of the active layer than in a region adjacent to a center of the active layer in the width direction.

In a transistor according to one embodiment of the present disclosure, the plurality of holes can be hydrogen discharge paths of the active layer and the gate insulating layer.

In a transistor according to one embodiment of the present disclosure, the plurality of holes can comprise a first group of hydrogen discharge paths having widths gradually increasing in the width direction from the edge to the center in the overlap area between the gate electrode and the active layer.

In a transistor according to one embodiment of the present disclosure, the hydrogen discharge paths of the first group can be spaced apart from the overlap region by an equal distance, respectively.

In a transistor according to one embodiment of the present disclosure, a region of the active layer not overlapping with the gate electrode can comprise a conductive region and the conductive region can overlap with the plurality of holes.

In a transistor according to one embodiment of the present disclosure, the active layer can comprise a channel in the overlap region thereof overlapping with the gate electrode and the plurality of holes can be parallel to the channel.

A transistor according to one embodiment of the present disclosure can further comprise a first source-drain electrode and a second source-drain electrode connected to the active layer through a first contact hole and a second contact hole, respectively, at the outside of the overlap area between the gate electrode and the active layer. The first contact hole and the second contact hole can overlap with at least a part of the plurality of holes, respectively.

In a transistor according to one embodiment of the present disclosure, the plurality of holes can comprise a first group of hydrogen discharge paths overlapping with the first contact hole and the second contact hole and a second group of hydrogen discharge paths having at least a region not overlapping with the active layer while being parallel to the first group of hydrogen discharge paths.

In a transistor according to one embodiment of the present disclosure, the second group of hydrogen discharge paths can be deeper than the first group of hydrogen discharge paths. A thickness of an insulating layer removed in the second group of hydrogen discharge paths can be greater than a thickness of an insulating layer removed in the first group of hydrogen discharge paths.

In a transistor according to one embodiment of the present disclosure, the hydrogen discharge paths of the first group can be spaced apart from the gate electrode by a first distance and the hydrogen discharge paths of the second group can be spaced apart from the gate electrode by a second distance greater than the first distance.

A transistor according to one embodiment of the present disclosure can further comprise a protective layer over the first and second source-drain electrodes. The protective layer can fill a plurality of hydrogen discharge paths of the second group.

In a transistor according to one embodiment of the present disclosure, an interlayer insulating layer can be provided between the gate insulating layer and the first and second source-drain electrodes. The plurality of holes can have removal portions in the interlayer insulating layer continuous to removal portions of the gate insulating layer, respectively.

In a transistor according to one embodiment of the present disclosure, the active layer can comprise an oxide semiconductor.

A transistor according to one embodiment of the present disclosure can further comprise a light shielding metal under the active layer. The light shielding metal can be electrically connected to the gate electrode.

A display device according to one embodiment of the present disclosure can comprise a substrate having an active area and a non-active area, a plurality of gate lines and a plurality of data lines intersecting each other to define a plurality of sub-pixels in the active area, a first transistor and a second transistor provided at at least one of the plurality of sub-pixels, a light emitting element connected to the second transistor; and a third transistor provided in the non-active area.

At least one of the first transistor, the second transistor, and the third transistor can comprise an active layer, a gate electrode having a region overlapping with the active layer, a gate insulating layer disposed between the active layer and the gate electrode, and a plurality of holes provided in the gate insulating layer at an outside of an overlap area between the gate electrode and the active layer.

A disposition density of the plurality of holes can be higher in a region adjacent to an edge of the active layer in a width direction of the active layer than in a region adjacent to a center of the active layer in the width direction.

In a display device according to one embodiment of the present disclosure, the third transistor can comprise the plurality of holes; and the active layer of the third transistor can have a greater width than each active layer of the first and second transistors.

In a display device according to one embodiment of the present disclosure, the plurality of holes can be provided at a gate-in-panel at the non-active area.

In a display device according to one embodiment of the present disclosure, the first transistor can comprise the plurality of holes. The gate electrode of the first transistor can be connected to a corresponding one of the gate lines.

In a display device according to one embodiment of the present disclosure, the plurality of holes can comprise a first group of hydrogen discharge paths having widths gradually increasing in the width direction from the edge to the center in the overlap area between the gate electrode and the active layer.

In a display device according to one embodiment of the present disclosure, a region of the active layer not overlapping with the gate electrode can comprise a conductive region. The disposition density of the plurality of holes in the conductive region can be higher at a portion thereof adjacent to the edge of the active layer in the width direction than at a portion thereof adjacent to the center of the active layer in the width direction.

A display device according to one embodiment of the present disclosure can further comprise a first source-drain electrode and a second source-drain electrode connected to the active layer through a first contact hole and a second contact hole, respectively, at the outside of the overlap area between the gate electrode and the active layer. The first contact hole and the second contact hole can overlap with at least a part of the plurality of holes, respectively.

In a display device according to one embodiment of the present disclosure, an interlayer insulating layer can be provided between the gate insulating layer and the first and second source-drain electrodes.

The plurality of holes can have removal portions in the interlayer insulating layer continuous to removal portions of the gate insulating layer, respectively.

In a display device according to one embodiment of the present disclosure, the plurality of holes can comprise a first group of hydrogen discharge paths overlapping with the first contact hole and the second contact hole in a first width and a second group of hydrogen discharge paths having at least a region not overlapping with the active layer while being parallel to the first group of hydrogen discharge paths.

In a display device according to one embodiment of the present disclosure, the second group of hydrogen discharge paths can be deeper than the first group of hydrogen discharge paths.

A thickness of an insulating layer removed in the second group of hydrogen discharge paths can be greater than a thickness of an insulating layer removed in the first group of hydrogen discharge paths.

In a display device according to one embodiment of the present disclosure, the hydrogen discharge paths of the first group can be spaced apart from the gate electrode by a first distance and the hydrogen discharge paths of the second group can be spaced apart from the gate electrode by a second distance greater than the first distance.

A display device according to one embodiment of the present disclosure can further comprise a protective layer covering the first to third transistors. The protective layer can fill the second group of hydrogen discharge paths.

The transistor of the present disclosure and the display device including the same have the following effects.

A transistor according to embodiments of the present disclosure includes a plurality of parallel hydrogen discharge paths provided through removal of a gate insulating layer at an outside of an overlap region between a gate electrode and an active layer, thereby preventing or minimizing diffusion of hydrogen generated during execution of a process. Accordingly, it can be possible to prevent an effective channel length variation caused by diffusion of a conductive region.

In the transistor according to the embodiment of the present disclosure, hole formation for the hydrogen discharge paths can be performed together with contact hole formation in a contact hole formation process. Accordingly, it can be possible to solve a problem such as hydrogen diffusion or the like without addition of a separate process and, as such, there is an advantage of process optimization.

A transistor according to embodiments of the present disclosure can prevent conductivity diffusion deepened at a central portion of the transistor by disposing hydrogen discharge paths to have different sizes in a width direction of an active layer in a structure in which a channel region defined by overlap of the active layer with a gate electrode is wide. That is, a hydrogen diffusion amount difference caused by a Joule heat generation amount difference among different regions can be compensated for by a size difference of hydrogen discharge paths and, as such, it can be possible to maintain effective channel lengths in a width direction to be equal or similar. Accordingly, it can be possible to prevent an effective channel length from decreasing abruptly at the central portion of the transistor in the width direction. As a result, a characteristic difference of the transistor among different regions, such as deviations of threshold voltage variation or the like can be prevented.

A transistor according to embodiments of the present disclosure is provided in an area requiring high power, such as the gate-in-panel (GIP), while having a wide-width structure, and a hydrogen discharge structure is provided within the structure of the transistor. Accordingly, it can be possible to prevent a variation in effective channel length of the transistor and, as such, to enhance reliability of the transistor.

A transistor according to embodiments of the present disclosure can reduce or minimize channel length deviations in different regions in a structure having a wide-width channel, thereby preventing a channel length variation proportional to a width increase and reducing width sensitivity. In this regard, a stable wide-width transistor can be realized. Accordingly, in implementation of the wide-width transistor, it can be possible to minimize a channel length margin and, as such, the transistor can be driven using low power, as compared to a structure having a channel length margin.

In a transistor according to embodiments of the present disclosure, it can be possible to reduce or minimize influence of hydrogen diffusion occurring after a contact hole formation process by removing, by thermal treatment, hydrogen in not only an active layer, but also in an insulating layer adjacent to the active layer, through first hydrogen discharge paths exposing a conductive region of the active layer and second hydrogen discharge paths formed in the insulating layer, except for the active layer.

In the transistor according to the embodiment of the present disclosure, hydrogen discharge paths can be formed together with contact holes in a contact hole formation process, without addition of a separate process. Accordingly, it can be possible to reduce use amounts of materials used in the overall manufacturing process, such as a deposition material, an etchant, etc. required upon addition of a separate process in the transistor and a display device including the transistor. Accordingly, it can be possible to provide a display device including a transistor capable of reducing greenhouse gases generated due to a manufacturing process.

The present disclosure enables application of a high-power wide-channel transistor having a small size while being capable of controlling a variation in effective channel length and reducing threshold voltage sensitivity. Accordingly, there is an advantage in that power consumption can be reduced and, as such, low-power driving is possible. As a result, there are environmental and social-sustainability advantages and, as such, environmental/social/governance (ESG) goals can be achieved.

The present disclosure described above is not limited to the above-described embodiments and the accompanying drawings. Accordingly, it will be understood by those skilled in the art that various substitutions, changes, and modifications can be made without departing from the scope of the disclosure.

What is claimed is:

1. A transistor comprising:
an active layer;
a gate electrode having a region overlapping with the active layer;
a gate insulating layer disposed between the active layer and the gate electrode; and
a plurality of holes disposed in the gate insulating layer at an outside of an overlap area between the gate electrode and the active layer,
wherein a disposition density of the plurality of holes is higher in a region adjacent to an edge of the active layer in a width direction of the active layer than in a region adjacent to a center of the active layer in the width direction.

2. The transistor according to claim 1, wherein the plurality of holes are hydrogen discharge paths of the active layer and the gate insulating layer.

3. The transistor according to claim 1, wherein the plurality of holes comprise a first group of hydrogen discharge paths having widths gradually increasing in the width direction from the edge to the center of the active layer in the overlap area between the gate electrode and the active layer.

4. The transistor according to claim 3, wherein the hydrogen discharge paths in the first group are spaced apart from the overlap area by an equal distance, respectively.

5. The transistor according to claim 1, wherein:
a region of the active layer not overlapping with the gate electrode comprises a conductive region, and
the conductive region overlaps with the plurality of holes.

6. The transistor according to claim 1, wherein:
the active layer comprises a channel in the overlap area thereof overlapping with the gate electrode, and
the plurality of holes are parallel to the channel of the active layer.

7. The transistor according to claim 1, further comprising:
a first source-drain electrode and a second source-drain electrode connected to the active layer through a first contact hole and a second contact hole, respectively, at the outside of the overlap area between the gate electrode and the active layer,
wherein the first contact hole and the second contact hole overlap with at least a part of the plurality of holes, respectively.

8. The transistor according to claim 7, wherein the plurality of holes comprise:
a first group of hydrogen discharge paths overlapping with the first contact hole and the second contact hole; and
a second group of hydrogen discharge paths having at least a region not overlapping with the active layer while being parallel to the first group of hydrogen discharge paths.

9. The transistor according to claim 8, wherein:
the second group of hydrogen discharge paths is deeper than the first group of hydrogen discharge paths, and
a thickness of an insulating layer removed in the second group of hydrogen discharge paths is greater than a thickness of an insulating layer removed in the first group of hydrogen discharge paths.

10. The transistor according to claim 8, wherein:
the hydrogen discharge paths in the first group are spaced apart from the gate electrode by a first distance, and
the hydrogen discharge paths in the second group are spaced apart from the gate electrode by a second distance greater than the first distance.

11. The transistor according to claim 8, further comprising:
a protective layer disposed over the first and second source-drain electrodes,
wherein the protective layer fills the hydrogen discharge paths in the second group.

12. The transistor according to claim 7, wherein:
an interlayer insulating layer is provided between the gate insulating layer and the first and second source-drain electrodes, and
the plurality of holes have removal portions in the interlayer insulating layer continuously to removal portions of the gate insulating layer, respectively.

13. The transistor according to claim 1, wherein the active layer comprises an oxide semiconductor.

14. The transistor according to claim 1, further comprising:
a light shielding metal layer disposed under the active layer,
wherein the light shielding metal layer is electrically connected to the gate electrode.

15. A display device comprising:
a substrate having an active area and a non-active area;
a plurality of gate lines and a plurality of data lines intersecting each other to define a plurality of sub-pixels in the active area;
a first transistor and a second transistor provided at at least one of the plurality of sub-pixels;
a light emitting element connected to the second transistor; and
a third transistor provided in the non-active area,
wherein at least one of the first transistor, the second transistor, and the third transistor comprises an active layer, a gate electrode having a region overlapping with the active layer, a gate insulating layer disposed between the active layer and the gate electrode, and a plurality of holes provided in the gate insulating layer at an outside of an overlap area between the gate electrode and the active layer, and
wherein a disposition density of the plurality of holes is higher in a region adjacent to an edge of the active layer in a width direction of the active layer than in a region adjacent to a center of the active layer in the width direction.

16. The display device according to claim 15, wherein:
the third transistor comprises the plurality of holes, and
the active layer of the third transistor has a greater width than each active layer of the first and second transistors.

17. The display device according to claim 15, wherein the plurality of holes are provided at a gate-in-panel at the non-active area.

18. The display device according to claim 15, wherein:
the first transistor comprises the plurality of holes, and
the gate electrode of the first transistor is connected to a corresponding one of the plurality of gate lines.

19. The display device according to claim 15, wherein the plurality of holes comprise a first group of hydrogen discharge paths having widths gradually increasing in the width direction from the edge to the center of the active layer in the overlap area between the gate electrode and the active layer.

20. The display device according to claim 15, wherein:
a region of the active layer not overlapping with the gate electrode comprises a conductive region, and
the disposition density of the plurality of holes in the conductive region is higher at a portion thereof adjacent to the edge of the active layer in the width direction than at a portion thereof adjacent to the center of the active layer in the width direction.

21. The display device according to claim 15, further comprising:
a first source-drain electrode and a second source-drain electrode connected to the active layer through a first contact hole and a second contact hole, respectively, at the outside of the overlap area between the gate electrode and the active layer,
wherein the first contact hole and the second contact hole overlap with at least a part of the plurality of holes, respectively.

22. The display device according to claim 21, wherein:
an interlayer insulating layer is provided between the gate insulating layer and the first and second source-drain electrodes, and
the plurality of holes have removal portions in the interlayer insulating layer continuously to removal portions of the gate insulating layer, respectively.

23. The display device according to claim 21, wherein the plurality of holes comprise:
a first group of hydrogen discharge paths overlapping with the first contact hole and the second contact hole in a first width; and
a second group of hydrogen discharge paths having at least a region not overlapping with the active layer while being parallel to the first group of hydrogen discharge paths.

24. The display device according to claim 23, wherein:
the second group of hydrogen discharge paths is deeper than the first group of hydrogen discharge paths, and
a thickness of an insulating layer removed in the second group of hydrogen discharge paths is greater than a thickness of an insulating layer removed in the first group of hydrogen discharge paths.

25. The display device according to claim 23, wherein:
the hydrogen discharge paths in the first group are spaced apart from the gate electrode by a first distance, and
the hydrogen discharge paths in the second group are spaced apart from the gate electrode by a second distance greater than the first distance.

26. The display device according to claim 23, further comprising:
a protective layer covering the first to third transistors,
wherein the protective layer fills the second group of hydrogen discharge paths.
